(19) United States
(12) Patent Application Publication
(10) Pub. No.: US 2023/0335995 A1
(43) Pub. Date: Oct. 19, 2023

(54) STATIONARY ENERGY STORAGE BATTERY AUGMENTATION

(71) Applicant: Mitsubishi Power Americas, Inc., Lake Mary, FL (US)

(72) Inventors: Craig Satoshi Brooker, Winter Springs, FL (US); Michael Thomas Leonard, South Park, PA (US); Michael McManus, Palm Coast, FL (US); Luca Tonini, Glenville, NY (US); Song Wu, Livingston, NJ (US)

(21) Appl. No.: 17/722,996

(22) Filed: Apr. 18, 2022

(51) Int. Cl. H02J 3/32; H02J 7/00

(52) U.S. Cl. CPC H02J 3/32; H02J 7/00036; H02J 7/00047; H02J 2207/20

(57) ABSTRACT

A battery system for storing electric energy on a grid system comprises a stationary energy storage facility comprising a first bank of batteries comprising a first plurality of batteries of a first type, wherein the first type comprises stationary storage batteries, a local power conversion system for receiving output of the first plurality of batteries and outputting power to the grid system, and a local controller for integrating and operating the local power conversion system with the first bank of batteries; an augmentation battery system comprising a second bank of batteries comprising a second plurality of batteries of a second type, wherein the second type of batteries comprises electric vehicle batteries, a secondary power conversion system for receiving output of the second plurality of batteries and outputting power to the local power conversion system, and a battery management system for operating the second bank of batteries, the battery management system comprising part of the electric vehicle batteries; and a translation battery management system configured to translate communications of the pack battery management system for communicating with the local controller.

### TECHNICAL FIELD

The present application pertains generally, but not by way of limitation, to distributed grid networks that provide electricity from power producers to end users. More specifically, but not by way of limitation, the present application relates to energy storage systems that can be used to store electrical power from a distributed grid network (“the grid”).

### BACKGROUND

Power plants typically supply power to the grid within a distributed network where voltage is provided at a constant amplitude or magnitude and frequency is maintained at a certain value within limits. As such, electrical power can be provided to end users in a consistent format. When the demand on the grid changes sufficiently, it can be desirable to bring additional power producers online or have power producers go offline or into a standby mode in order to more closely match production with demand.

In order to more smoothly match power production with power demand, stationery energy storage systems can be used to store excess power generated by the producers or provide power to the grid to meet excess demand from the end users. Examples, of typical stationary energy storage systems comprise Battery Energy Storage Systems (BESSs). A BESS can utilize large scale rechargeable batteries that are configured for operation with the grid. These batteries can be configured to last years, but eventually degrade due to the passing of time, usage or both. Eventually, the batteries can degrade to a point where the BESS is no longer effective, and the batteries need to be replaced in order to maintain the effectiveness, e.g., power output, of the BESS.

It has been suggested to use second life EV batteries for stationary purposes. Examples of second life EV batteries used in stationary applications are described in Pub. No. US 2021/0050729 A1 to Arvind et al., titled “Integration of Second-Use of Li-Ion Batteries in Power Generation” and Pub. No. WO 2014/181081 A1 to Mukherjee et al., titled “Energy Transfer Apparatus and Distribution Control Method Therefor.”

### OVERVIEW

The present inventors have recognized, among other things, that the integration of second use electric vehicle batteries into stationary energy storage systems can be difficult due to the different intended purpose of electric vehicle batteries. For example, electric vehicle batteries are smaller in size and capacity and have vastly different power demands and discharge and charge cycles. Similarly, each vehicle manufacturer can have different battery requirements depending on the specific design of each electric vehicle in which the batteries are used. Furthermore, each vehicle manufacturer can have widely varying battery management systems that, among other things, control the flow of data into and out of the battery.

The present subject matter can help provide solutions to these problems and other problems, such as by providing devices and systems for 1) communicating disparate information from electric vehicle batteries of different types from each other to a stationary energy storage battery facility local controller in a useful format, such as can be performed by xBMS 32 of FIG. 2, and 2) controlling safe electrical connection of electric vehicle batteries to the grid, such as can be performed by connection device 40 of FIG. 3, and methods for 1) translating different types and formats of data from electric vehicle batteries to a local controller for an existing stationary energy storage facility with only desired data in a useable format, such as can be performed by the method illustrated in FIG. 6, 2) connecting electric vehicle batteries to the grid in a safe manner for discharge and charge modes, such as can be performed by the method illustrated in FIG. 4, and 3) balancing battery charge within packs of electric vehicle batteries, such as can be performed by the method illustrated in FIG. 5.

In an example, a battery system for storing electric energy on a grid system comprises a stationary energy storage facility comprising a first bank of batteries comprising a first plurality of batteries of a first type, wherein the first type comprises stationary storage batteries, a local power conversion system for receiving output of the first plurality of batteries and outputting power to the grid system, and a local controller for integrating and operating the local power conversion system with the first bank of batteries; an augmentation battery system comprising a second bank of batteries comprising a second plurality of batteries of a second type, wherein the second type of batteries comprises electric vehicle batteries, a secondary power conversion system for receiving output of the second plurality of batteries and outputting power to the local power conversion system, and a battery management system for operating the second bank of batteries, the battery management system comprising part of the electric vehicle batteries; and a translation battery management system configured to translate communications of the pack battery management system for communicating with the local controller.

In another example, a of augmenting stationary storage batteries of a stationary energy storage facility for a grid system can comprise installing a plurality of partially degraded electric vehicle batteries at the stationary energy storage facility, connecting electric power output of the plurality of partially degraded electric vehicle batteries to a local power conversion system of the stationary energy storage facility, establishing communication between the plurality of partially degraded electric vehicle batteries and a translation battery management system, and establishing communication between the translation battery management system and a local controller of the stationary energy storage facility, wherein the translation battery management system is configured to translate communications of the plurality of partially degraded electric vehicle batteries for communicating with the local controller.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

FIG. 1 is a schematic diagram illustrating a conventional stationary energy storage facility using rechargeable stationary batteries.

FIG. 2 is a schematic diagram illustrating a stationary energy storage facility augmented with used rechargeable electric vehicle (EV) batteries and a translation battery management system to facilitate communication between the rechargeable EV batteries and a local controller for the rechargeable stationary batteries.

FIG. 3 is a schematic diagram illustrating a connection device for controlling connection of the rechargeable EV batteries to a secondary power conversion system that connects to the grid.

FIG. 4 is a line diagram illustrating control logic that can be executed by a translation battery management system to operate the connection device of FIG. 3 for standby, charge and discharge modes.

FIG. 5 is a line diagram illustrating control logic that can be executed by a translation battery management system to perform pack balancing of rechargeable EV batteries of FIGS. 2 and 3.

FIG. 6 is a schematic diagram illustrating control logic that can be executed by a translation battery management system to communicate data between the rechargeable EV batteries and a local controller.

FIG. 7 is a stationary energy storage facility augmented with rechargeable EV batteries and a translation battery management system connected to a transformer.

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

### DETAILED DESCRIPTION

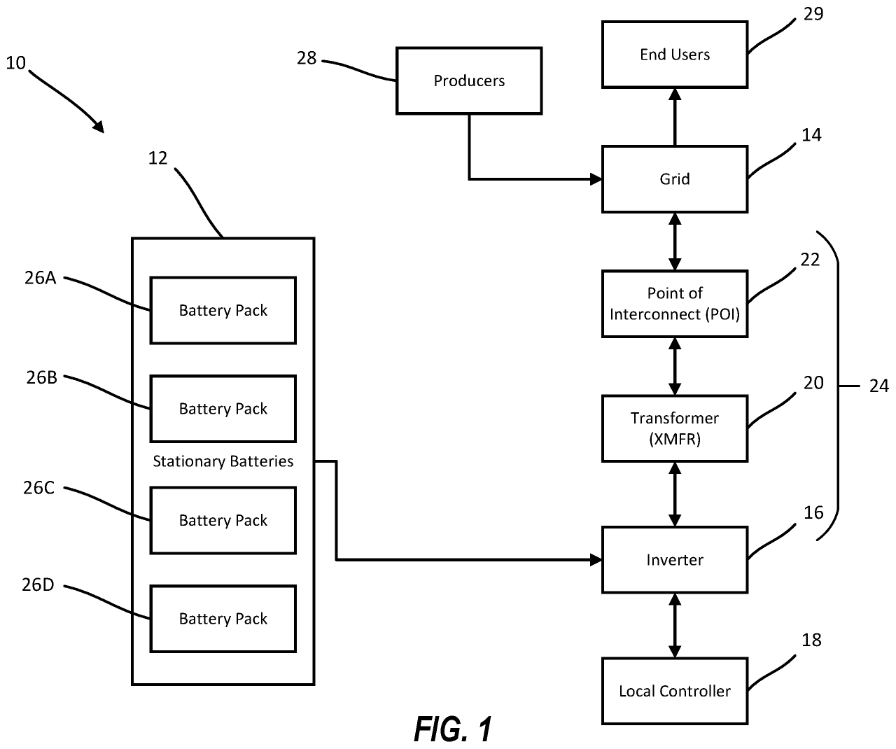

FIG. 1 is a schematic diagram illustrating stationary energy storage facility 10 using rechargeable stationary batteries 12. Batteries 12 can be connected to inverter 16, which can be in communication with local controller 18 and transformer 20. Transformer 20 can be connected to point of interconnect (POI) 22. POI 22 can be connected to grid 14. Inverter 16, transformer 20 and POI 22 can be collectively referred to as local power conversion system (PCS) 24. For convenience, PCS 24 is described as including inverter 16, but the various components of PCS 24 can be separate or arranged in various combinations. Batteries 12 can comprise a plurality of battery packs 26A, 26B, 26C and 26D. Power can be provided to grid 14 by power producers 28. Power available from grid 14 can be consumed by end users 29.

Stationary energy storage facility 10 can be configured to export power to and import power from grid 14. When demand on grid 14 is low, producers 28 connected to grid 14 can have excess energy production capabilities. It can be advantageous to store the energy generated by producers 28 at batteries 12. For example, it can be more efficient to continue to produce energy and store the excess energy than to shut down or ramp down production, particularly at gas turbine combined cycle (GTCC) power production facilities where there can be performance and emissions penalties in ramping down operation of gas turbine engines. Additionally, producers 28 that take advantage of renewable energy sources, such as wind and solar, can store power generated by these methods when environmental conditions are favorable for wind and solar energy production for later use when environmental conditions are unfavorable for wind and solar energy production. When demand on grid 14 is high, energy stored in batteries 12 can be discharged to grid 14. Batteries 12 can, therefore, smooth out changes in demand for electricity relative to power producers, such as by providing time for additional energy producers to come online or currently producing energy producers to ramp up output.

Batteries 12 can comprise a battery energy storage system (BESS). Each of battery packs 26A-26D can comprise a plurality of individual rechargeable batteries configured to store electrical energy that can be provided to grid 14 upon appropriate demand levels. Batteries of battery packs 26A-26D can utilize different technologies, including Lithium-ion (Li-ion), lead-acid, nickel-cadmium, nickel-metal-hydride, and sodium-sulfur. However, newly constructed stationary energy storage facilities typically use the same technology for all the batteries in the numerous battery packs in order to simplify the construction and standardize the control operations for each battery and battery pack. In examples, batteries of a BESS can operate with various voltages, such as 1000V DC or greater, and BESS systems can be modular and can provide energy on the order of MWhs to GWhs.

Inverter 16 can comprise a system or device for receiving the output of batteries 12. Inverter 16 can convert between different types of current, such as direct current (DC) and alternating current (AC). In typical grid systems, batteries 12 provide DC power and grid 14 can operate with AC power. As such, inverter 16 is configured to convert DC power from batteries 12 to AC power for grid 14, and vice versa, depending on whether batteries 12 are discharging or charging. Inverter 16 can additionally scale both current and voltage levels, appropriately between batteries 12 and transformer 20.

Transformer (XMFR) 20 can comprise a device or system for transforming the voltages between inverter 16 and grid 14. Furthermore, additional transformers can be used to achieve the desired voltage, such as by including a transformer in POI 22. For example, XMFR 20 can step-up or step-down the voltages between inverter 16 and grid 14. In examples, XMFR 20 can step-down the voltage from inverter 16, and vice versa. In examples, XMFR 20 can step-up the voltage output of inverter 16 from typically 480 V to 690 V to a typical system voltage of 34.5 kV or more, and subsequently the POI 22 can further step-up the system voltage to that of grid 14.

Point of interconnect (POI) 22 can comprise the point where electricity is exchanged with grid 14. POI 22 can comprise the specific, physical location where power from local power conversion system 24 is exchanged with grid 14. POI 22 can comprise one or more of wires, switches, contactors, relays and circuit breakers.

Grid 14 can comprise a distributed network where power is exchanged at a certain voltage, and frequency is maintained at a certain value within limits. Grid 14 provides a common electrical network for producers 28 to provide power and for consumers to receive power. Producers can comprise any type of energy producers, such as GTCC power plants, coal power plants, nuclear power plants and renewable energy power plants. End users 29 can comprise residential, commercial and industrial users.

Local controller 18 can be configured to operate inverter 16, XMFR 20 and eventually POI 22, such as by reading information from batteries 12 and receiving information from a grid controller and operating inverter 16, XMFR 20 and POI 22 to provide a desired or requested service to grid 14 from batteries 12. Local controller 18 can be in communication with a power plant controller, which can be in communication with a plurality of local controllers. Local controller 18 can be configured to issue commands to PCS 24 based on the operating state of batteries 12. Batteries 12 can operate in different modes, such as a standby/disconnected mode or an active/connected mode that can be used for charging and discharging. Batteries 12 can operate in a connected mode to provide power to grid 14 or to receive power from grid 14.

Batteries 12 can have a battery management system (BMS), which is not shown in FIG. 1 for clarity. The BMS can be configured to read and monitor voltage, temperature, coolant flow and current of each battery in packs 26A-26D, as well as other parameters. The BMS can protect each of the individual battery cells of packs 26A-26D from overheating and operating at other adverse conditions based on voltage and current. Thus, the BMS can be configured to ensure safe and reliable operation of batteries 12. Additionally, the BMS can balance the individual batteries within each of packs 26A-26D and balance packs 26A-26D relative to each other. Since each of packs 26A-26D is typically operating with the same kind of battery cell, the BMS can be configured to operate at the individual battery level, at a pack level or for the entirety of batteries 12, such as at local controller 18. The BMS can be specifically configured to operate with the conventions, e.g., battery information types and formats, of stationary energy storage facilities, such as BESS.

Over time the batteries of battery packs 26A-26D can degrade. For example, the capacity of each battery can be reduced (“Capacity Fade”) and the resistance of each battery can increase (“Resistance Increase”). Thus, the energy rating of the battery can be reduced, which can reduce the time for the battery to become discharged or reduce the amount of energy that can be provided to grid 14.

As such, it can be desirable to provide additional capacity to stationary energy storage facility 10 in the form of additional rechargeable batteries. Sometimes, the capacity of stationary energy storage facility 10 can be increased by adding new batteries of the same type used in battery packs 26A-26D. Such a method is easy to implement since the new batteries can be selected to have the same BMS, chemistry, form factor and performance characteristics as the old batteries, thereby allowing these batteries to be integrated into the existing system both mechanically and electrically in a similar fashion as the existing batteries. However, the addition of new batteries requires that new resources be used to make the new batteries, which can have adverse environmental impacts. Additionally, the added new batteries will themselves eventually become degraded, increasing the number of batteries that will eventually need to be recycled at the end of life of the stationary energy storage system. Furthermore, the projected lifespan of the new batteries can often exceed the remaining lifespan of the stationary energy storage system, which could potentially lead to the recycling of batteries having useful life remaining. An additional disadvantage of using batteries of the same type can be that the augmentation provided by the added new batteries must be integrated within the parameters dictated by the existing control system architecture, e.g., the specific BMS conventions. That is, without the addition of extra DC/DC converters and possibly other equipment, there is not much flexibility in terms of how the added batteries can be integrated as they typically will need to have the same BMS.

As is discussed below, the present disclosure provides devices, systems and methods for allowing a variety of different rechargeable batteries to be added to batteries 12 to add additional capacity to stationary energy storage facility 10. In particular, the present disclosure provides ways to add partially degraded electric vehicle batteries that can be different from each other and in different states of degradation to be added to batteries 12 in such a manner that local controller 18 will be able to receive relevant information from the augmentation batteries, balance the augmentation batteries to be efficiently used together and allow the augmentation batteries to be connected to grid 14 in a safe manner for charging and discharging.

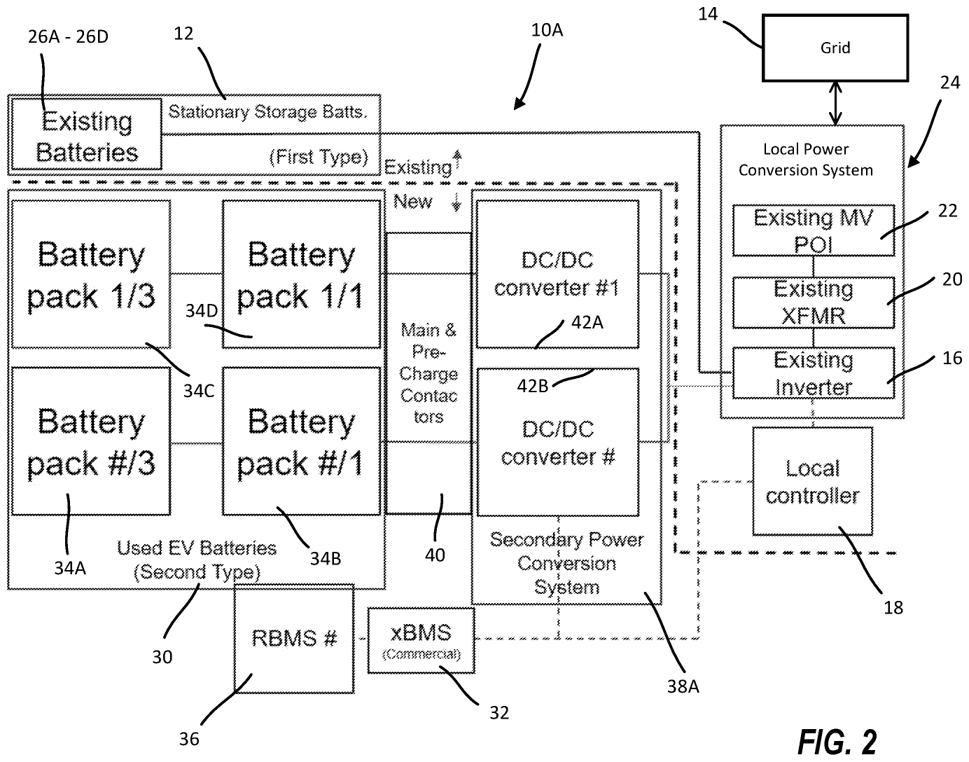

FIG. 2 is a schematic diagram illustrating stationary energy storage facility 10A of FIG. 1 augmented with rechargeable EV batteries 30 and translation battery management system (xBMS) 32 to facilitate communication between rechargeable battery packs 34A, 34B, 34C and 34D and local controller 18 for rechargeable stationary battery packs 26A-26D. Rack battery management system 36 can be used to provide communication between battery packs 34A-34D and xBMS 32. In examples, RBMS 36 and xBMS 32 can be incorporated into the same object. xBMS 32 can be in communication with secondary power conversion system 38A and local controller 18. Secondary power conversion system 38A can comprise DC/DC converter 42A and DC/DC converter 42B. Battery packs 34A-34D can be in electrical connection with rack battery management system 36 and secondary power conversion system (PCS) 38A via connection device 40. Local controller 18 can be in communication with inverter 16 of local power conversion system (PCS) 24. Local PCS 24 can comprise inverter 16, XMFR 20 and POI 22. For convenience, PCS 24 is described as including inverter 16, but the various components of PCS 24 can be separate or arranged in various combinations. As such, stationary energy storage facility 10A can be configured similarly as stationary energy storage facility 10 of FIG. 1, with the addition of batteries 30, xBMS 32, RBMS 36, secondary PCS 38A and connection device 40. In examples, connection device 40 can be part of secondary PCS 38A.

Batteries of packs 34A-34D can comprise different types of batteries, including Lithium-ion (Li-ion), lead-acid, nickel-cadmium, nickel-metal-hydride, and sodium-sulfur. The batteries of packs 34A-34D can utilize electric vehicle (EV) batteries. In examples, battery packs 34A-34D can typically be between 60% to 80% state of health (SOH). Batteries of packs 34A-34D can be repackaged and integrated without having to modify the form factor of the EV batteries. Other components, such as DC/DC converters, disconnect switches, controls, cooling, etc. can be added to batteries of packs 34A-34D to allow the batteries to be deployed and integrated into existing stationary energy storage projects for system energy augmentation purposes, as discussed herein.

Batteries 30 are discussed as being arranged in packs 34A-34D, but can also be arranged in racks, as is known in the art. For a consumer vehicle, the EV batteries are typically controlled on a single pack basis via a Pack BMS (“PBMS”). For larger commercial vehicles, multiple packs are controlled via a Rack BMS (“RBMS”). The devices and methods of the present disclosure can be applied to second use batteries arranged in packs and racks. Furthermore, FIG. 2 illustrates multiple groupings of three battery packs, but a greater or lesser number of packs can be used in the same or other groupings.

The characteristics of electric vehicle batteries and stationary storage batteries can be different. For example, electric vehicle batteries can have high energy and power density requirements, discharge cycles in the range of approximately a few thousand, a lifetime of about five to seven years and generally higher discharge rates. Stationary storage batteries can have lower energy and power density requirements, desirable discharge cycles above several thousand, a lifetime of ten to twenty years and slower discharge rates. Thus, the characteristics of battery packs 34A-34D, which can comprise electric vehicle batteries, can be different than the characteristics of stationary battery packs 26A-26D, which are designed for stationary grid applications. As such, battery management systems for stationary energy storage batteries and electric vehicle batteries can operate in different manners, e.g., with different information and with different formats.

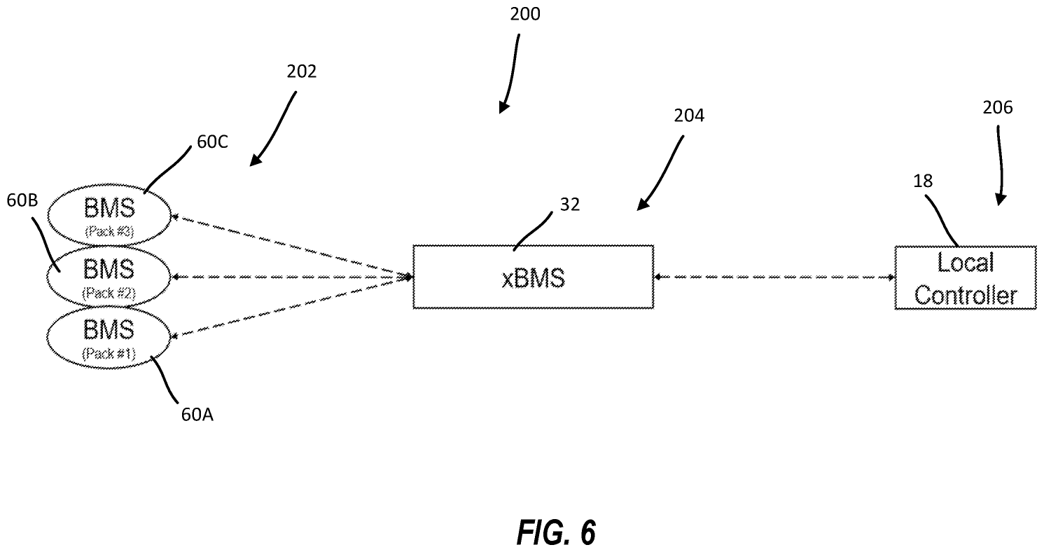

In view of the foregoing, the information provided to local controller 18 from batteries 12 can be different than the information generated by RBMS 36. Thus, if the information generated by RBMS 36 were provided directly to local controller 18, local controller 18 might not be able to correctly recognize or process the information, thereby rendering batteries 30 useless or causing a potential safety hazard. xBMS 32 of the present disclosure can be configured to receive and process information from RBMS 36 and provide the information to local controller 18 in an useable form and with useable content. Depending on the type of electric vehicle battery, xBMS 32 can translate signals from either a PBMS or a RBMS and communicate with the existing local controller 18. Operation of xBMS 32 is described in greater detail with reference to FIG. 6.

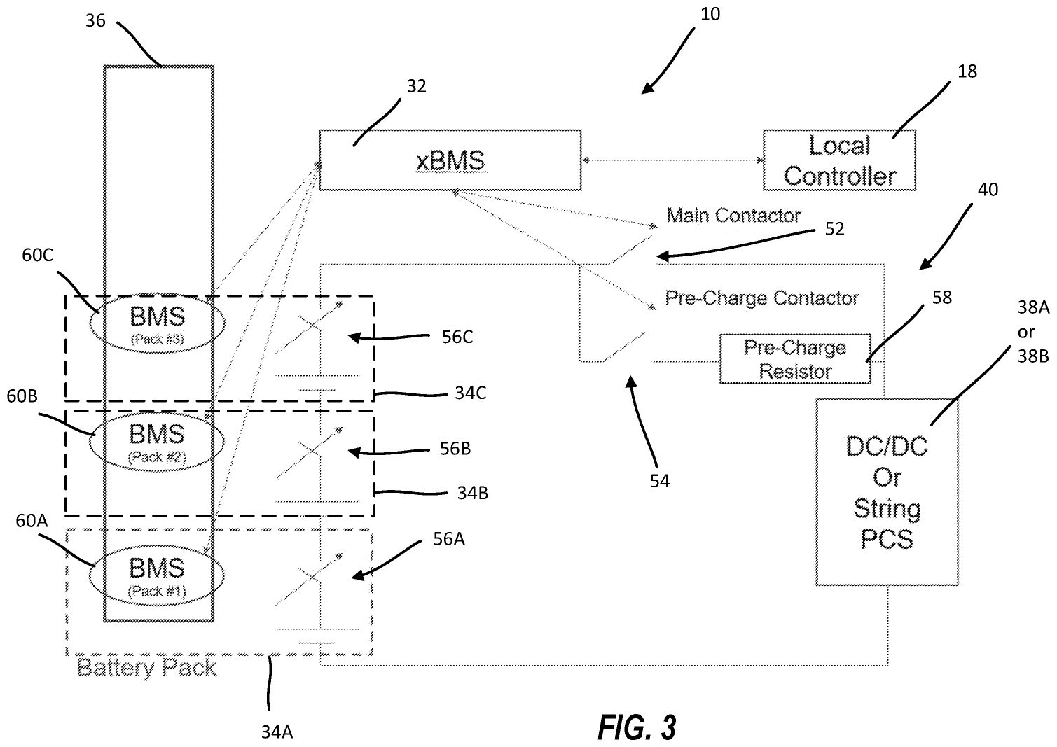

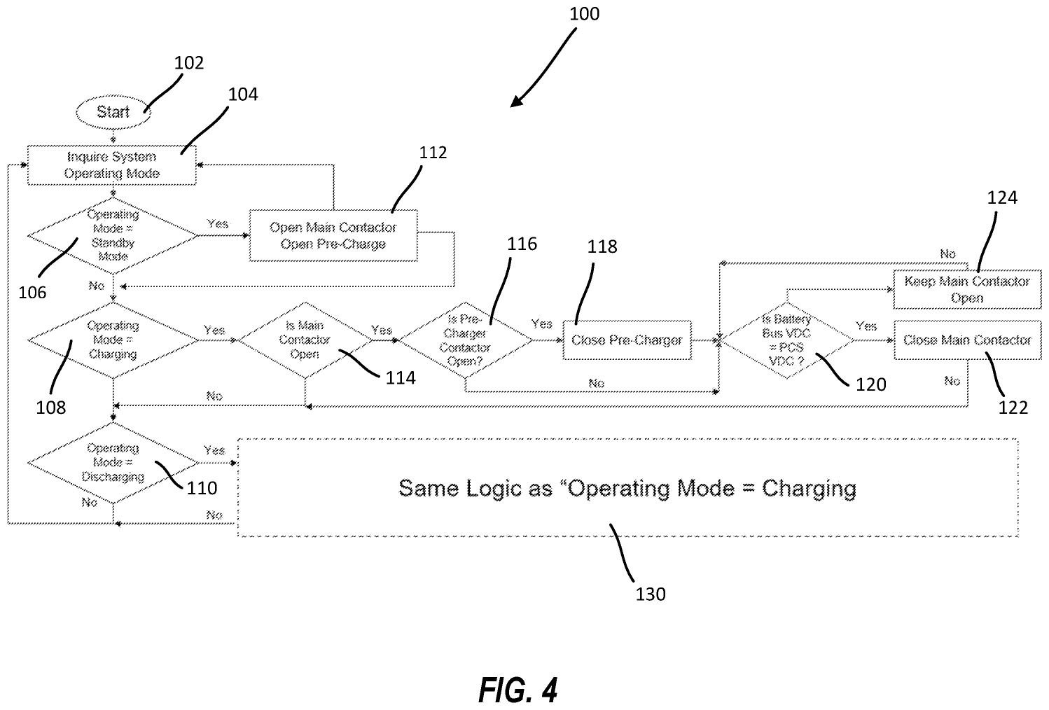

Furthermore, batteries 30 can be provided with connection device 40 that can facilitate integration of the power of batteries 30 with the power of batteries 12. Connection device 40 can be part of secondary power conversion system 38A, batteries 30 or a standalone device. Connection device 40 can provide electrical connection between batteries 30 and local PCS 24 via secondary PCS 38A. Secondary PCS 38A can receive the power from connection device 40 such that local PCS 24 receives the power from batteries 30 at the same voltage as from batteries 12. Connection device 40 can comprise a plurality of switches or contacts that can be controlled by xBMS 32 or local controller 18 to bring the power from batteries 30 online in a controlled and safe manner, as is discussed below in detail with reference to FIGS. 3 and 4.

In the configuration of FIG. 2, POI 22 can comprise a Medium Voltage Point of Interconnect (MV POI), but can comprise a High Voltage Point of Interconnect (HV POI) in additional configurations. Secondary PCS 38A and xBMS 32 can maintain functionality with a Medium Voltage POI. Battery packs 34A-34D of batteries 30 can be wired in series to optimize the voltage level with the existing PCS voltage levels and can be connected via new DC/DC converters 42A and 42B to inverter 16, which can allow optimization of usable battery energy when operating and pairing with batteries 12. Two DC/DC converters are described, though any suitable number can be used.

Facility 10A can be configured to, among other things: (1) maximize to the extent possible, the existing DC voltage levels of AC/DC inverter 16 at 1,500V DC, which is typically used in practice; and (2) allow for integration into local controller 18 through flexible local control system topology, as discussed with reference to FIGS. 4 and 6. Depending on the type batteries used for batteries 30, the amount of battery packs or modules connected in series can differ to achieve the 1,500V DC threshold and can impact physical packaging. xBMS 32 can take the initially non-compatible signals from RBMS 36 and enable the integration and control with local controller 18. xBMS 32 can be incorporated as a new physical BMS between RBMS 36 and local controller 18, as illustrated, or as a new BMS control card that would be inserted into RBMS 36 to replace or supplement the information stored therein. In examples, xBMS 32 can be configured as a standalone device, or as a card or component attached to or plugged into an existing component. In examples, xBMS 32 can comprise a memory card, a programmable logic controller, (PLC), a printed circuit board (PCB) and the like. In examples, xBMS 32 and RMBS 36 can be combined into a single PCB.

FIG. 3 is a schematic diagram illustrating connection device 40 of FIG. 2 for controlling connection of rechargeable battery packs 34A-34C to secondary PCS 38A. Connection device 40 can be part of secondary power conversion system 38A, batteries 30 or a standalone device. Connection device 40 can comprise main contactor 52, pre-charge contactor 54, pack contactors 56A, 56B and 56C and pre-charge resistor 58. In examples, pack contactors 56A, 56B and 56C can comprise components of battery packs 34A-34C, respectively. In additional examples, pack contactors 56A, 56B and 56C can be omitted. Battery packs 34A, 34B and 34C can have pack battery management systems (BMSs) 60A, 60B and 60C, respectively. FIG. 3 only shows battery packs 56A-56C, but can include any number of battery packs arranged in various configurations. Similarly, batteries 36 can include less than three or more than four packs of batteries.

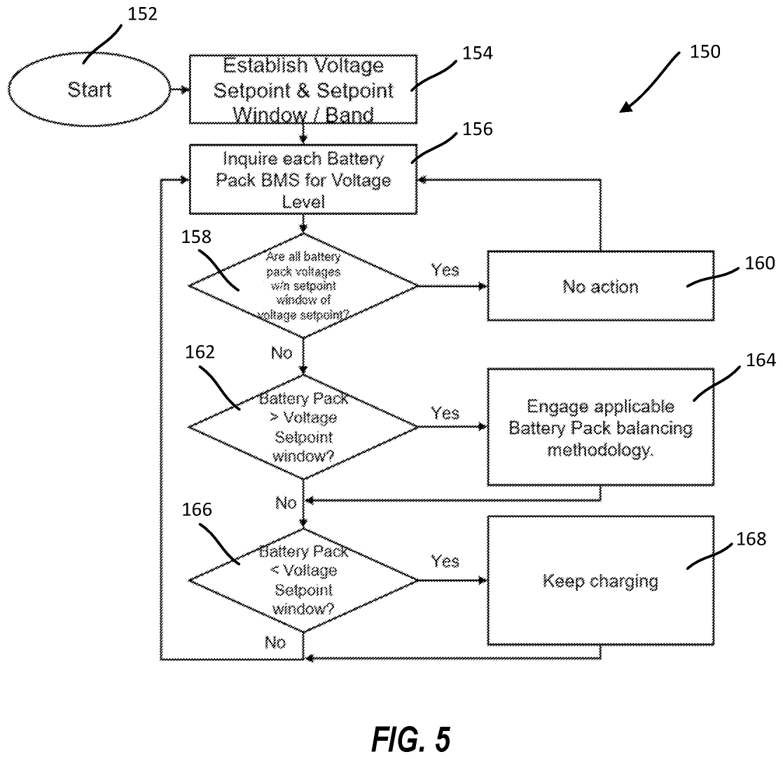

Each of pack BMSs 60A-60C can be in electronic communication with xBMS 32. xBMS 32 can be configured to control BMSs 60A-60C for each battery of packs 34A-34C to ensure proper operation in conjunction with the other packs. xBMS 32 can control electrical contactors 52, 54 and 56A-56C and in what sequence they close/open, as is discussed with reference to FIG. 4. In examples, electrical contactors 52 and 54 can be part of secondary PCS 38A and xBMS 32 can send signals to secondary PCS 38A to control contactors 52 and 54. xBMS 32 can control voltage balancing between EV packs, as is discussed with reference to FIG. 5, such as through each of BMSs 60A-60C or a rack BMS.

Pack contactors 56A-56C can be configured to receive power from the battery cells comprising battery packs 34A-34C, respectively. Pack contactors 56A-56C can also be in electrical communication with main contactor 52 and pre-charge contactor 54. Pack contactors 56A-56C can comprise switches or breakers that can be operated to selectively provide electrical connection between battery packs 34A-34C and main contactor 52 and pre-charge contactor 54. Pack contactors 56A-56C can be controlled by xBMS 32 through each of BMS 60A-60C, or via a rack BMS if used, based on input from local controller 18. Pack contactors 56A-56C can be controlled individually as needed to operate each of battery packs 34A-34C or can be operated collectively.

xBMS 32 can additionally control main contactor 52 and pre-charge contactor 54. Main contactor 52 and pre-charge contactor 54 can be arranged in parallel such that power from batteries 36 can be in communication with secondary PCS 38A when either one of main contactor 52 and pre-charge contactor 54 is closed. Pre-charge resistor 58 can be in series with pre-charge contactor 54. In examples, main contactor 52 can comprise a 1,500V contactor. Typically, existing contactors on EV packs are not rated for such high voltage levels.

Local controller 18 can provide commands to xBMS 32 regarding when it is desirable to have battery packs 34A-34D connected to grid 14 or disconnected from grid in a standby mode. In some situations, battery packs 34A-34D can be connected to grid 14 without power flow. When in a standby mode, main contactor 52 and pre-charge contactor 54 can be opened, thereby disconnecting battery packs 34A-34D from grid 14 regardless of the state of contactors 56A-56C. In charge and discharge modes, main contactor 52, and contactors 56A-56C can be closed to bring all of battery packs 34A-34C into electrical communication with grid 14. As mentioned, if it is desirable to leave one or more of battery packs 34A-34C offline for various purposes, such as maintenance, individual ones of contactors 56A-56C can be opened to allow access to the corresponding battery pack without interfering with the operation of stationary energy storage facility 10A. Control of main contactor 52 and pre-charge contactor 54 to bring battery packs 34A-34D into communication with grid 14 for charge and discharge modes as is described with reference to FIG. 4. In charge and discharge modes, battery packs 34A-34D can be connected to grid 14. In a standby or idle mode, battery packs 34A-34D can be disconnected from grid 14.

XBMS 32 can operate as a standalone device or can be connected (e.g., networked) to other machines. In a networked deployment, xBMS 32 can operate in the capacity of a server machine, a client machine, or both in server-client network environments. In an example, xBMS 32 can act as a peer machine in peer-to-peer (P2P) (or other distributed) network environment. XBMS 32 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine.

XBMS 32 can comprise a computer system and can include a hardware processor (e.g., a central processing unit (CPU), a graphics processing unit (GPU), a hardware processor core, or any combination thereof), main memory and static memory, some or all of which may communicate with each other via an interlink, which can comprise a bus. XBMS 32 can further include a display unit, an alphanumeric input device (e.g., a keyboard), and a user interface (UI) navigation device (e.g., a mouse). In an example, the display unit, input device and UI navigation device can be a touch screen display. XBMS 32 can additionally include a storage device (e.g., drive unit), signal generation device (e.g., a speaker), network interface device, and one or more sensors, such as a global positioning system (GPS) sensor, compass, accelerometer, temperature sensor, pressure sensor or other sensor. XBMS 32 can include output controller, such as a serial (e.g., Universal Serial Bus (USB), parallel, or other wired or wireless (e.g., infrared (IR), near field communication (NFC), etc.) connection to communicate or control one or more peripheral devices (e.g., a printer, card reader, etc.).

The storage device can include a machine readable medium on which is stored one or more sets of data structures or instructions (e.g., software) embodying or utilized by any one or more of the techniques or functions described herein, such as for operating stationary energy storage facilities 10, 10A and 10B and executing the control logic illustrated in FIGS. 4-6. The instructions can also reside, completely or at least partially, within the main memory, within the static memory, or within the hardware processor during execution thereof by xBMS 32. In examples, one or any combination of the hardware processor, the main memory, the static memory, or the storage device can constitute machine readable media.

The machine readable medium can be a single medium. However, the term “machine readable medium” can include a single medium or multiple media (e.g., a centralized or distributed database, and/or associated caches and servers) configured to store the one or more instructions. The term “machine readable medium” can include any medium that is capable of storing, encoding, or carrying instructions for execution by xBMS 32 and that cause xBMS 32 to perform any one or more of the techniques of the present disclosure, or that is capable of storing, encoding or carrying data structures used by or associated with such instructions. Non-limiting machine readable medium examples may include solid-state memories, and optical and magnetic media. In examples, the machine readable medium can comprise RAM or ROM.

The instructions can further be transmitted or received over the communications network using a transmission medium via a network interface device utilizing any one of a number of transfer protocols (e.g., frame relay, internet protocol (IP), transmission control protocol (TCP), user datagram protocol (UDP), hypertext transfer protocol (HTTP), CANBus etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device can include one or more physical jacks (e.g., Ethernet, coaxial, fiber optic, or phone jacks) or one or more antennas to connect to a communications network. In an example, the network interface device can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by xBMS 32, and includes digital or analog communications signals or other intangible medium to facilitate communication of such software.

In additional examples, local controller 18 can be configured to have the same or similar hardware and software components as xBMS 32 as described above.

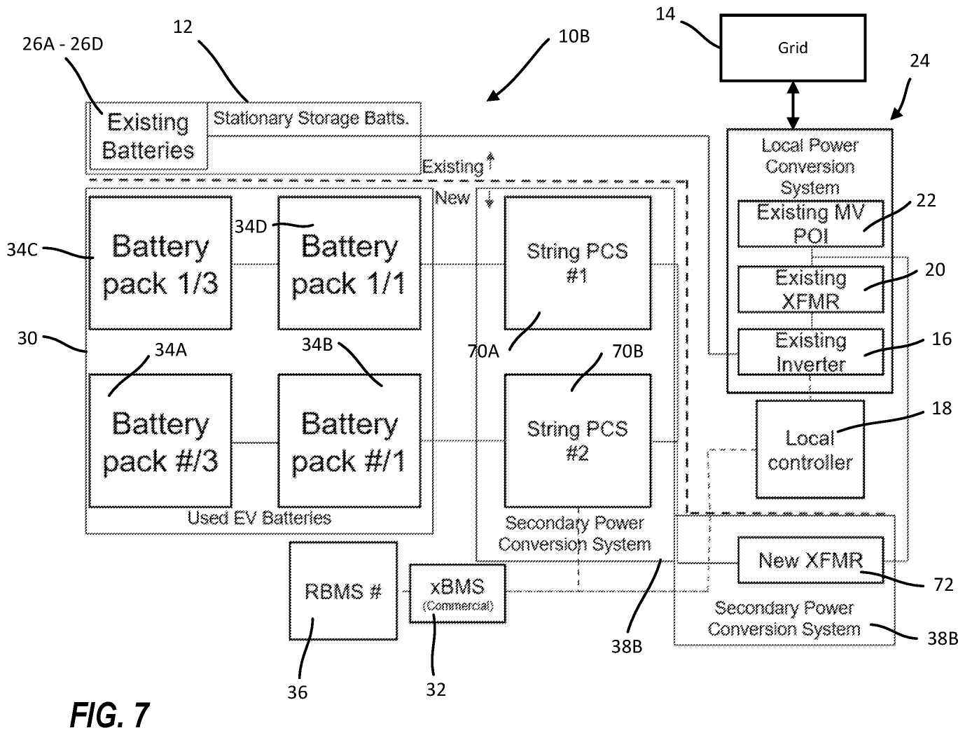

FIG. 4 is a line diagram illustrating method 100 for operating connection device 40 of FIG. 3. Method 100 can operate in a standby mode at step 106, a charge mode at step 108 and a discharge mode at step 110. As mentioned, standby mode of step 106 can comprise a mode where battery packs 34A-34C are idle and not connected to grid 14, charge mode of step 108 and discharge mode of step 110 can comprise modes where battery packs 34A-34C are connected to grid 14 to import or export power. Method 100 can control the operation of main contactor 52 and pre-charge contactor 54, as well as contactors 56A-56C, to allow current from grid 14 to flow into battery packs 34A-34C during a charge mode and current from battery packs 34A-34C to flow into grid 14 during a discharge mode. Method 100 can be performed by xBMS 32 to operate main contactor 52 and pre-charge contactor 54 in controlled sequences to ensure that battery packs 34A-34C are in satisfactory condition, e.g., health, temperature, charge, to be charged and discharged. For example, xBMS 32 can control when DC pre-charge happens through pre-charge contactor 54 and pre-charge resistor 58. xBMS 32 can execute logic of method 100 to ensure bus level voltages are the same before any transient conditions happen. Note, FIG. 4 is discussed with reference to secondary PCS 38A of FIG. 2, but can be executed with secondary PCS 38B of FIG. 7 as well.

At step 102, xBMS 32 can start method 100, such as by monitoring the operation of facility 10A. In examples, xBMS 32 can determine if facility 10A is operating to discharge power to grid 14, receive power from grid 14 or is in a standby mode not connected to grid 14. In examples, xBMS 32 can communicate with local controller 18 to receive updates regarding the status of facility 10A. xBMS 32 can receive input from local controller 18 regarding the status of grid 14 and local controller 18 can prompt RBMS 36 to operate in standby, charge or discharge modes, through XBMS 32.

At step 104, xBMS 32 can determine an operating mode for RBMS 36. In examples, the operating mode for RBMS 36 can correspond to an operating mode of facility 10A. Step 104 can encompass xBMS 32 providing instructions to RBMS 36 indicating the operating mode in which RBMS 36 should be operating in. At step 106, xBMS 32 can put EV batteries 30 in a standby mode. At step 108, xBMS 32 can put EV batteries 30 in a charge mode. At step 110, xBMS 32 can put EV batteries 30 in a discharge mode.

xBMS 32 can cycle through steps 106-110 to find the operating mode that augmentation batteries should be in based on input from steps 102 and 104.

At step 106, RBMS 36 can determine that EV batteries 30 should be in a standby mode, such as by receiving input from xBMS 32. Thus, at step 106, xBMS 32 can inquire if EV batteries 30 are in a standby mode and make adjustments to EV batteries 30 and connection device 40 to put augmentation batteries into a standby mode. Thus, if RBMS 36 needs to be in a standby mode, method 100 can move to step 112. However, if RBMS 36 has determined that EV batteries 30 should not be in a standby mode, method 100 can move through step 106 to step 108 without taking action. In examples, a sequence for disconnecting battery packs 34A-34D can comprise stopping DC/DC converters 42A and 42B, open contact 52 and, if desired, open contacts 56A-56C.

At step 112, if xBMS 32 has determined facility 10A is in a standby mode, xBMS 32 can take action to put EV batteries 30 in a standby mode. xBMS 32 can open main contactor 52 at step 112, thereby removing EV batteries 30 from electrical connection with secondary PCS 38A and grid 14. In order to put battery packs 34A-34D into contact with grid 14, xBMS 32 can execute steps 108 or 110. In an example, xBMS 32 can start DC/DC converters 42A and 42B to form a DC voltage on the battery side, close contacts 56A-56C to move voltage BUS close to battery level, close contact 54, close contact 52 when the voltages are within mVs on both sides and then open contact 54. In an example, xBMS 32 can close contacts 56A-56C, close contact 52, allow DC/DC converters 42A and 42B to have a precharge circuit.

At step 108, RBMS 36 can determine that EV batteries 30 should be in a charge mode, such as by receiving input from xBMS 32. Thus, at step 108, xBMS 32 can inquire if EV batteries 30 are in a charge mode and make adjustments to EV batteries 30 and connection device 40 to put augmentation batteries into a charge mode. Thus, if RBMS 36 needs to be in a charge mode, method 100 can move to step 114. However, if RBMS 36 has determined that EV batteries 30 should not be in a charge mode, method 100 can move through step 108 to step 110 without taking action.

At step 114, if xBMS 32 has determined facility 10A is in a charge mode, xBMS 32 can take action to put EV batteries 30 in a charge mode so that EV batteries 30 can be put in electrical connection with secondary PCS 38A and grid 14. At step 114, xBMS 32 can check to see if main contactor 52 is open. If main contactor 52 is open, method 100 can advance to step 116 to continue to put EV batteries 30 in a charge mode. If main contactor 52 is closed, method 100 can determine that augmentation batteries are already in a charge or discharge mode, or some other state, and can move to step 110.

At step 116, xBMS 32 can determine if pre-charge contactor 54 is open. If pre-charge contactor 54 is open, method 100 can advance to step 118 to continue to put EV batteries 30 in a charge mode. If pre-charge contactor 54 is closed, method 100 can skip ahead to step 120 to continue to put EV batteries 30 in a charge mode. Thus, if both contactor 52 and contactor 54 are open, xBMS 32 can know that connection device 40 is properly situated for RBMS 36 being in a standby mode and can take steps to safely transition RBMS 36 to charge mode in steps 120-124.

At step 118, xBMS 32 can close pre-charge contactor 54 and then move to step 120 to transition EV batteries 30 from the standby mode to the charge mode. Closing of pre-charge contactor 54 can put batteries 30 in electric communication with secondary PCS 38A and grid 14 through pre-charge resistor 58. Pre-charge resistor 58 can prevent voltage at secondary PCS 38A from slamming batteries 30. Pre-charge resistor 58 can be sized to control the inrush current to level the voltage between batteries 30 and secondary PCS 38A. In examples, pre-charge resistor 58 can have a resistance on the order of 100 Ohms for a 200 W to 400 W system, but other resistances can be used.

At step 120, xBMS 32 can check to determine if the BUS voltage of battery packs 34A-34D is equal to the BUS voltage of secondary PCS 38A. In particular, the voltage of the BUS for battery packs 34A-34D should equal, or within an acceptable tolerance band of equal based on conventional practice, the voltage of the BUS of secondary PCS 38A, which indicates that batteries 30 are at the desired voltage to be charged. As such, batteries 30 can be ready to safely receive or provide power from/to grid 14 without pre-charge resistor 58 by having main contactor 52 being closed. Thus, if the BUS voltage battery packs 34A-34D is inside the allowed voltage range to the BUS voltage of secondary PCS 38A, xBMS 32 can close main contactor 52 at step 122, thereby bringing battery packs 34A-34D into electrical connection with grid 14. Current flow will bypass pre-charge resistor 58 because main contactor 52 provides a path of lesser resistance, then pre-charge resistor 58 can be disconnected opening 54

From step 122, method 100 can move to step 110 after main contactor 52 is closed. Method 100 can cycle through method 100 starting from step 102 after continuing through step 110, assuming the operating mode of facility 10A has not changed. Thus, batteries can continue to receive power from grid 14 until xBMS 32 has determined that batteries no longer need charging. At which point, xBMS 32 can put RMBS 36 into a standby mode. Thus, as method 100 can continue through steps 110, 102 and 104, method 100 can enter step 106 to put batteries 30 in a standby mode by stopping DC/DC converter 38A and then opening main contactor 52.

When first entering the charge mode from step 120, if the BUS voltage battery packs 34A-34D is not equal to the BUS voltage of secondary PCS 38A, xBMS 32 can maintain main contactor 52 in an open state at step 124, thereby preventing battery packs 34A-34D from coming into electrical connection with grid 14 without pre-charge resistor 58 and method 100 can move to step 124. Thus, current can continue to flow through pre-charge resistor 58 to equalize the BUS voltage of battery packs 34A-34D and the BUS voltage of secondary PCS 38A.

From step 124, if the BUS voltage of battery packs 34A-34D is not equal to the BUS voltage of augmentation power conversion system 38A, method 100 can move back to step 120 to see if the BUS voltage of battery packs 34A-34D has levelized with the BUS voltage of secondary PCS 38A via receiving controlled current through pre-charge resistor 58 and pre-charge contactor 54.

Method 100 can move between steps 106, 108 and 110 based on the relative differences between or equality of the BUS voltage of battery packs 34A-34D and the BUS voltage of secondary power conversion system 38A.

At step 110, if xBMS 32 determines that facility 10A is in a discharge mode, xBMS 32 can execute discharging instructions 130. In examples, discharging instructions can be the same as charging instructions at steps 114-124, except that xBMS 32 will be looking to bring batteries 30 in a charged state into electrical communication with grid 14. Thus, steps 120, 122 and 124 can repeat until it is safe bring batteries 30 into full connection with grid 14 through main contactor 52 so that power from batteries 30 can be discharged to grid 14. Again, this process can repeat until xBMS 32 determines that facility 10A should be in a different mode.

Method of FIG. 4 is an example sequence of steps that can be executed by xBMS 32 and RBMS 36, with cooperation from local controller 18, to control contactors 52-56C to allow battery packs 34A-34C to be brought into electrical connection with power of grid 14 and power of batteries 12 in a safe manner to prevent damage to batteries 30 and stationary energy storage facility 10. For example, pre-charge contactor 54 can be used to allow initial current to and from batteries 30 to be at a safe, low level to allow the BUS voltages to which the BUS voltage of battery packs 34A-34C are coming into contact with to equalize, thereby better allowing for battery packs 34A-34C to receive the full power of grid 14 and batteries 12.

FIG. 5 is a line diagram illustrating method 150 for controlling pack balancing of battery packs 34A-34D of FIGS. 2 and 3. For example, because each of packs 34A-34D can be different from each other and can be in different states of degradation, it can be useful to put each of packs 34A-34D into a similar electrical state for interacting with secondary PCS 38A and batteries 12.

At step 152, xBMS 32 can start method 100, such as by monitoring the status of battery packs 34A-34D. xBMS 32 can periodically run method 100, such as after a discharge operation or after a charge operation of FIG. 4.

At step 154, a voltage setpoint and setpoint window can be established. The voltage setpoint can be a voltage at which battery packs 34A-34D are desired to be maintained, such as at full charge. The setpoint window can be the acceptable tolerance band from which the voltage can deviate from the setpoint. The setpoint window can be defined as a threshold bandwidth or as a +/−quantity or percentage from the setpoint. For example, a desired setpoint voltage can be 1500 V and the desired setpoint window can be 1490 V to 1510 V or FS 0.1%, since it is desirable not to exceed 1500V. The setpoint and setpoint window can be programmed into xBMS 32 and can be fixed or can be entered into xBMS 32 via a user input. The setpoint and setpoint window can be selected to account for differences between the batteries in battery packs 34A-34D. For example, if the voltages of the batteries of each of battery packs 34A-34D differ, the voltage setpoint can be set to the lowest voltage of battery packs 34A-34D.

At step 156, xBMS 32 can inquire each of battery packs 34A-34D to determine the voltage level of each of battery packs 34A-34D. Voltage readings of each of battery packs 34A-34D can be stored in memory of xBMS 32 or local controller 18.

At step 158, xBMS 32 can determine if the voltage of each of battery packs 34A-34D are within the setpoint window established at step 154. In examples, the voltage of each of battery packs 34A-34D can be subtracted from the voltage setpoint to obtain a pack voltage differential value that can be stored in memory of xBMS 32 or local controller 18. The pack voltage differential values can be compared to the setpoint window values. If the voltages of all battery packs 34A-34D are within the setpoint window, method 150 can move to step 160.

At step 160, no action can be taken because the voltages of all of packs 34A-34D are considered balanced. If the voltages of all battery packs 34A-34D are not within the setpoint window, method 150 can move to step 162.

At step 162, xBMS 32 can, for any of battery packs 34A-34D having a voltage outside the setpoint window, determine if the voltage of such battery pack is above the setpoint voltage. If the voltage is above the setpoint voltage, method 150 can move to step 164.

At step 164, xBMS 32 can employ a battery pack balancing strategy to bring each of the voltages of battery packs 34A-34D to within the setpoint window. For example, power of a battery pack exceeding the setpoint voltage can be drained off or moved to an underpowered battery pack. The voltage can be drained off through a resistor if the voltage of each of the other battery packs is at or above the voltage setpoint. The voltage can be transferred to another battery pack if one or more of battery packs 34A-34D is below the voltage set point.

A variety of cell balancing techniques can be used to balance packs 34A-34D. Examples of cell balancing techniques include passive cell balancing, active cell balancing and lossless cell balancing. Passive cell balancing can involve charging all battery cells or packs and simultaneously bleeding off, through a resistor, from fully charged batteries until the other cells or packs are fully charged. However, passive cell balancing can be performed at other state of charge levels than full charge. Active cell balancing can involve moving charge from stronger cells or packs to weaker cells or packs such that energy is not wasted through a resistor as in passive cell balancing. Battery packs 34A-34D can be balanced according to techniques described in S, H. Overview of cell balancing methods for Li-ion battery technology. Energy Storage. 2021; 3: e203. https://doi.org/10.1002/est2.203, which is hereby incorporated by reference in its entirety. Lossless cell balancing can involve using hardware and software to electrically remove fully charged cells or packs from the charging process while continuing to charge the other cells or packs. After each of the batteries having a voltage exceeding the setpoint voltage is balanced, method 150 can move to step 166.

At step 166, xBMS 32 can, for any of battery packs 34A-34D having a voltage outside the setpoint window, determine if the voltage of such battery pack is below the setpoint voltage. If the voltage is below the setpoint voltage, method 150 can move to step 168.

At step 168, xBMS 32 can continue to charge battery packs 34A-34D to bring each of the voltages of battery packs 34A-34D to within the setpoint window. For example, power of a battery pack falling short of the setpoint voltage can be connected to grid 14 to receive additional power. After each of the batteries having a voltage exceeding the setpoint voltage is balanced, method 150 can move to step 156 to repeat method 150.

FIG. 6 is a schematic diagram illustrating method 200 comprising translation logic that can be executed by xBMS 32 to communicate data between rechargeable EV batteries 30 and local controller 18.

At step 202, BMS 60C, BMS 60B and BMS 60C can provide data to xBMS 32, including state of health and state of charge. FIG. 6 is described with reference to pack BMSs, but can additionally be implemented with rack BMSs. However, each of BMS 60A-60C has access to significantly more data than is desired by local controller 18. For example, BMSs 60A-60C can be from electric vehicles and can have significantly more information requirements relating not only operation of the electric vehicle battery, but the operation of the electric vehicle that the battery is intended to be used with for items such as regenerative braking, passenger climate control, passenger entertainment, communication devices, etc. Typically, an electric vehicle BMS will output all of the data available to the electric vehicle controller, which can sort and utilize all the data in appropriate manners. In some cases, there can be upwards of 5,000 different signals generated by an electric vehicle BMS.

At step 204, xBMS 32 can be configured to receive, sort, combine and eliminate data and information from BMSs 60A-60C and provide only relevant information to local controller 18. xBMS 32 can filter and aggregate the relevant signals from BMS 60A-60C and pass information to local controller 18, including Cell—Voltage, Temperature, Pack—Current, state of health (SOH), state of charge (SOC), Capacity, Energy, Power, Ambient Temperature, Operating Status and others. xBMS 32 can filter out signals from BMS 60A-60C relating to operation of the batteries specific to electric vehicle operation, such as those relating to regenerative braking, passenger climate control, navigation, entertainment, communication, safety features and the like.

xBMS 32 can assign unique addresses and identifiers to each of packs 34A-34C. xBMS 32 can convert and organize signals from various EV Industry Protocols to Energy Storage Industry Protocols. xBMS 32 can additionally convert information from local controller 18 for use with BMSs 60A-60C. In examples, the unique identifiers can comprise numbers, alphanumeric characters, serial numbers, network or port addresses, or other physical, digital or visual indicia that can allow xBMS 32 to distinguish between each of packs 34A-34C and assign information and data specific to each of packs 34A-34C thereto.

At step 206, local controller 18 can obtain information from BMSs 60A-60C and provide instructions to local PCS 24 to provide power to grid 14 from batteries 30 or vice versa through secondary PCS 38A and connection device 40. xBMS 32 can coordinate operation of connection device 40 based on translated information sent to and received from local controller 18.

In sum, xBMS 32 can be configured to pass only relevant signals between BMSs 60A-60C and local controller 18. xBMS 32 can combine information from BMSs 60A-60C for use by local controller 18 to treat all of battery packs 34A-34D as one unit and can disaggregate or divide instructions from local controller 18 for use by BMSs 60A-60C. xBMS 32 can provide format conversions for data from BMSs 60A-60C and local controller 18. For example, xBMS 32 can convert Controller Area Network (CAN) data to MODbus data. xBMS can adds unique identifiers to each of battery packs 34A-34D to allow information from local controller to be delivered to specific locations within batteries 30.

FIG. 7 is a schematic diagram illustrating stationary energy storage facility 10B of FIG. 1 augmented with rechargeable EV batteries 30 and translation battery management system (xBMS) 32 to facilitate communication between rechargeable battery packs 34A, 34B, 34C and 34D and local controller 18 for the rechargeable stationary battery packs 26A-26D.

Rack battery management system 36 can be used to provide communication between battery packs 34A-34D and xBMS 32. xBMS 32 can be in communication with secondary power conversion system 38B and local controller 18. Secondary power conversion system 38B can comprise PCS converter 70A and PCS converter 70B. Battery packs 34A-34D can be in communication with rack battery management system 36 via connection device 40. Local controller 18 can be in communication with local power conversion system 24. Local PCS 24 can comprise inverter 16, XMFR 20 and POI 22. Secondary PCS 38B can be in communication with local PCS 24 via transformer 72.

Facility 10B can be the same as facility 10A except for secondary PCS 38A can be replaced with secondary PCS 38B. Secondary PCS 38B can be configured to convert power similarly as secondary PCS 38A except rather than having DC/DC converters 42A and 42B that simply changing the direct current voltage, PCS 38B can include transformer 72 to also change the voltage of batteries 30. Thus, transformer 72 can connect to local PCS 24 between POI 22 and transformer 20, as opposed to secondary PCS 38A connecting to local PCS 24 at inverter 16. In the configuration of stationary energy storage facility 10A of FIG. 2, DC/DC converters 42A and 42B can make the voltages compatible with existing batteries 26A-26D in order to tie into the same PCS, local PCS 24, and subsequently the same MV transformer, XFMR 20. In the configuration of stationary energy storage facility 10B of FIG. 7, string PCSs 70A and 70B and transformer 72 are used. For SESF 10A, the operation of existing batteries 26A-26D and additional EV batteries 34A-34C are more closely aligned and in synch because they are tied to the same PCS and transformer. In SESF 10B, the battery packs are not tied to the same PCS and transformer and therefore are more independent when it comes to operation.

In the configuration of FIG. 7, Point of Interconnect 22 is maintained but transformer 74 is added. Batteries 30 can be wired in series to optimize the voltage level with the existing PCS voltage levels and can be connected via PCS 70A and 70B to the existing facility transformer 20. This can decouple the control of batteries 30 from operating requirement and boundaries of existing Inverter 16.

In examples of the present disclosure, xBMS 32 can inquire as to the state of health of battery packs 34A-34D. If the state of health of each of battery packs 34A-34D is acceptable, xBMS 32 can inquire as to the and state of charge of battery packs 34A-34D. If battery packs 34A-34D are not fully charged, xBMS 32 can perform a pack balancing technique of FIG. 5 on battery packs 34A-34D and can then subsequently connect battery packs 34A-34D to grid 14 for charging per the technique of FIG. 4. Instructions for charging battery packs 34A-34D can be provided to local controller 18 via the technique of FIG. 6. If needed or desired, xBMS 32 can again perform a back balancing technique on battery packs 34A-34D with fully or nearly fully charged battery packs 34A-34D. Once battery packs 34A-34D are suitably charged and balanced, xBMS 32 can put battery packs 34A-34D in a standby mode and wait for instructions from local controller 18 to bring battery packs 34A-34D online for discharge of power to grid 14, such as by performing the technique of FIG. 4. After receiving instructions for discharge from local controller 18, xBMS 32 can put battery packs in a discharge mode and can communicate information to local controller 18 via the technique of FIG. 6 to provide instructions for operating battery packs 34A-34D.

The systems and methods of the present disclosure can achieve numerous benefits by reusing degraded electric vehicle batteries that are no longer effective for use in electric vehicles, but that still have functionality. 1) Reuse of the electric vehicle batteries can mitigate the environmental impact of used electric vehicle batteries by, for example, reducing the demand for new stationary storage batteries. 2) The present disclosure, particularly the translation battery management devices discussed herein, can allow for “mix-and-match” of electric vehicle batteries with various characteristics including C-rates, pack voltage levels, form factors, battery management systems and chemistries for use with stationary energy storage batteries. 3) The present disclosure can allow for the matching of the life and degradation profile of electric vehicle batteries with existing stationary storage batteries and optimizing the dispatching characteristics of the combined system. 4) The present disclosure can allow for flexible design of a local control system for augmenting batteries by facilitating integration of any or most designs of rechargeable batteries with stationary conversion batteries. Use of second life batteries also reduces the burden on and capacity scale up rate of battery recycling facilities.

### Various Notes & Examples

Example 1 is a battery system for storing electric energy on a grid system, the battery system comprising: a stationary energy storage facility comprising: a first bank of batteries comprising a first plurality of batteries of a first type, wherein the first type comprises stationary storage batteries; a local power conversion system for receiving output of the first plurality of batteries and outputting power to the grid system; and a local controller for integrating and operating the local power conversion system with the first bank of batteries; an augmentation battery system comprising: a second bank of batteries comprising a second plurality of batteries of a second type, wherein the second type of batteries comprises electric vehicle batteries; a secondary power conversion system for receiving output of the second plurality of batteries and outputting power to the local power conversion system; and a battery management system for operating the second bank of batteries, the battery management system comprising part of the electric vehicle batteries; and a translation battery management system configured to translate communications of the pack battery management system for communicating with the local controller.

In Example 2, the subject matter of Example 1 optionally includes a connection device for controlling connection of the second plurality of batteries to the secondary power conversion system; wherein the connection device is configured to match a BUS voltage of the second bank of batteries with a BUS voltage of the secondary power conversion system.

In Example 3, the subject matter of Example 2 optionally includes wherein the connection device comprises: a main contactor for selectively connecting the second plurality of batteries directly to the secondary power conversion system; and a pre-charge contactor for selectively connecting the second plurality of batteries to the secondary power conversion system through a pre-charge resistor.

In Example 4, the subject matter of Example 3 optionally includes a pack contactor connecting the second plurality of batteries to the connection device.

In Example 5, the subject matter of any one or more of Examples 2-4 optionally include wherein the translation battery management system is configured to operate the connection device to put the second plurality of batteries into different operation modes comprising standby, charge and discharge modes.

In Example 6, the subject matter of any one or more of Examples 1-5 optionally include wherein the local power conversion system comprises: an inverter; a transformer in communication with the inverter; and a point of interconnect for the grid system in communication with the transformer.

In Example 7, the subject matter of Example 6 optionally includes herein the secondary power conversion system comprises: a DC-to-DC converter connecting the second plurality of batteries and the inverter.

In Example 8, the subject matter of any one or more of Examples 6-7 optionally include wherein the secondary power conversion system comprises: a string power conversion system connected to the second plurality of batteries; and a transformer connecting the string power conversion system with the point of interconnect.

In Example 9, the subject matter of any one or more of Examples 1-8 optionally include wherein the stationary storage batteries and electric vehicle batteries are different in at least one of manufacturer, chemistry and state of health.

In Example 10, the subject matter of Example 9 optionally includes wherein the translation battery management system controls operation of the second plurality of batteries for operation with the first plurality of batteries.

In Example 11, the subject matter of Example 10 optionally includes wherein the translation battery management system is configured to filter signals from the pack battery management system not needed by the local controller.

In Example 12, the subject matter of Example 11 optionally includes wherein the translation battery management system is configured to filter signals from the second plurality of batteries relating to operation of electric vehicles.

In Example 13, the subject matter of any one or more of Examples 10-12 optionally include wherein the second plurality of batteries comprises a plurality of packs of batteries of the second type.

In Example 14, the subject matter of Example 13 optionally includes wherein the translation battery management system is configured to balance charge of each of the plurality of packs of batteries of the second type.

In Example 15, the subject matter of any one or more of Examples 10-14 optionally include wherein the translation battery management system comprises a card inserted into the pack battery management system, the card comprising memory including instructions for coordinating operation of the second type of batteries with the first type of batteries.

In Example 16, the subject matter of any one or more of Examples 10-15 optionally include a local battery management system for the first plurality of batteries.

In Example 17, the subject matter of Example 16 optionally includes wherein the local controller interacts with the local battery management system.

In Example 18, the subject matter of any one or more of Examples 16-17 optionally include wherein the local battery management system is configured to communicate with the first type of batteries and not the second type of batteries.

Example 19 is a method of augmenting stationary storage batteries of a stationary energy storage facility for a grid system, the method comprising: installing a plurality of partially degraded electric vehicle batteries at the stationary energy storage facility; connecting electric power output of the plurality of partially degraded electric vehicle batteries to a local power conversion system of the stationary energy storage facility; establishing communication between the plurality of partially degraded electric vehicle batteries and a translation battery management system; and establishing communication between the translation battery management system and a local controller of the stationary energy storage facility; wherein the translation battery management system is configured to translate communications of the plurality of partially degraded electric vehicle batteries for communicating with the local controller.

In Example 20, the subject matter of Example 19 optionally includes wherein the stationary storage batteries and the plurality of partially degraded electric vehicle batteries are different in at least one of manufacturer, chemistry and state of health.

In Example 21, the subject matter of Example 20 optionally includes controlling operation of the plurality of partially degraded electric vehicle batteries with the translation battery management system for operation with the stationary storage batteries.

In Example 22, the subject matter of Example 21 optionally includes conveying signals from the plurality of partially degraded electric vehicle batteries to the local controller relating to cell voltage, cell temperature, current, state of health, state of charge, energy capacity and operating status with the translation battery management system.

In Example 23, the subject matter of any one or more of Examples 21-22 optionally include filtering signals from the plurality of partially degraded electric vehicle batteries not needed by the local controller with the translation battery management system.

In Example 24, the subject matter of Example 23 optionally includes filtering signals from the plurality of partially degraded electric vehicle batteries relating to operation of electric vehicles.

In Example 25, the subject matter of any one or more of Examples 19-24 optionally include using the translation battery management system to communicate with: a local battery management system of the local controller configured to communicate with the stationary storage batteries; and a rack battery management system of the plurality of partially degraded electric vehicle batteries.

In Example 26, the subject matter of Example 25 optionally includes converting Controller Area Network data signals from the rack battery management system of the plurality of partially degraded electric vehicle batteries to Modbus signals with the translation battery management system.

In Example 27, the subject matter of any one or more of Examples 19-26 optionally include adding unique battery pack identifiers to communication signals from each plurality of partially degraded electric vehicle batteries to Modbus signals with the translation battery management system.

In Example 28, the subject matter of any one or more of Examples 19-27 optionally include establishing connection between the plurality of partially degraded electric vehicle batteries and a secondary power conversion system by controlling a connection device with the translation battery management system.

In Example 29, the subject matter of Example 28 optionally includes determining if operating in standby mode or battery mode; if operating in the standby mode, disconnecting the plurality of partially degraded electric vehicle batteries from the secondary power conversion system; and if operating in the battery mode: opening a main contactor directly connecting the plurality of partially degraded electric vehicle batteries with the secondary power conversion system; closing a pre-charge contactor connecting the plurality of partially degraded electric vehicle batteries with the secondary power conversion system via a pre-charge resistor; and closing the main contactor when a voltage of the plurality of partially degraded electric vehicle batteries is equal to a voltage of the secondary power conversion system.

In Example 30, the subject matter of any one or more of Examples 19-29 optionally include balancing voltages of each of the plurality of partially degraded electric vehicle batteries with the translation battery management system.

In Example 31, the subject matter of Example 30 optionally includes wherein balancing voltages of each of the plurality of partially degraded electric vehicle batteries comprises: establishing a voltage setpoint and a voltage band; inquiring each of the plurality of partially degraded electric vehicle batteries for a voltage level; determining if voltage of each of the plurality of partially degraded electric vehicle batteries is within the voltage band; charging the plurality of partially degraded electric vehicle batteries if the voltage of each of the plurality of partially degraded electric vehicle batteries is less than the voltage setpoint; and employing a pack balancing technique if voltage of each of the plurality of partially degraded electric vehicle batteries is greater than voltage setpoint.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A battery system for storing electric energy on a grid system, the battery system comprising:
a stationary energy storage facility comprising:
a first bank of batteries comprising a first plurality of batteries of a first type, wherein the first type comprises stationary storage batteries;
a local power conversion system for receiving output of the first plurality of batteries and outputting power to the grid system; and
a local controller for integrating and operating the local power conversion system with the first bank of batteries;
an augmentation battery system comprising:
a second bank of batteries comprising a second plurality of batteries of a second type, wherein the second type of batteries comprises electric vehicle batteries;
a secondary power conversion system for receiving output of the second plurality of batteries and outputting power to the local power conversion system; and
a battery management system for operating the second bank of batteries, the battery management system comprising part of the electric vehicle batteries; and
a translation battery management system configured to translate communications of the pack battery management system for communicating with the local controller.

2. The battery system of claim 1, further comprising:
a connection device for controlling connection of the second plurality of batteries to the secondary power conversion system;
wherein the connection device is configured to match a BUS voltage of the second bank of batteries with a BUS voltage of the secondary power conversion system.

3. The battery system of claim 2, wherein the connection device comprises:
a main contactor for selectively connecting the second plurality of batteries directly to the secondary power conversion system; and
a pre-charge contactor for selectively connecting the second plurality of batteries to the secondary power conversion system through a pre-charge resistor.

4. The battery system of claim 3, further comprising a pack contactor connecting the second plurality of batteries to the connection device.

5. The battery system of claim 2, wherein the translation battery management system is configured to operate the connection device to put the second plurality of batteries into different operation modes comprising standby, charge and discharge modes.

6. The battery system of claim 1, wherein the local power conversion system comprises:
an inverter;
a transformer in communication with the inverter; and
a point of interconnect for the grid system in communication with the transformer.

7. The battery system of claim 6, herein the secondary power conversion system comprises:
a DC-to-DC converter connecting the second plurality of batteries and the inverter.

8. The battery system of claim 6, wherein the secondary power conversion system comprises:
a string power conversion system connected to the second plurality of batteries; and
a transformer connecting the string power conversion system with the point of interconnect.

9. The battery system of claim 1, wherein the stationary storage batteries and electric vehicle batteries are different in at least one of manufacturer, chemistry and state of health.

10. The battery system of claim 9, wherein the translation battery management system controls operation of the second plurality of batteries for operation with the first plurality of batteries.

11. The battery system of claim 10, wherein the translation battery management system is configured to filter signals from the pack battery management system not needed by the local controller.

12. The battery system of claim 11, wherein the translation battery management system is configured to filter signals from the second plurality of batteries relating to operation of electric vehicles.

13. The battery system of claim 10, wherein the second plurality of batteries comprises a plurality of packs of batteries of the second type.

14. The battery system of claim 13, wherein the translation battery management system is configured to balance charge of each of the plurality of packs of batteries of the second type.

15. The battery system of claim 10, wherein the translation battery management system comprises a card inserted into the pack battery management system, the card comprising memory including instructions for coordinating operation of the second type of batteries with the first type of batteries.

16. The battery system of claim 10, further comprising a local battery management system for the first plurality of batteries.

17. The battery system of claim 16, wherein the local controller interacts with the local battery management system.

18. The battery system of claim 16, wherein the local battery management system is configured to communicate with the first type of batteries and not the second type of batteries.

19. A method of augmenting stationary storage batteries of a stationary energy storage facility for a grid system, the method comprising:
installing a plurality of partially degraded electric vehicle batteries at the stationary energy storage facility;
connecting electric power output of the plurality of partially degraded electric vehicle batteries to a local power conversion system of the stationary energy storage facility;
establishing communication between the plurality of partially degraded electric vehicle batteries and a translation battery management system; and
establishing communication between the translation battery management system and a local controller of the stationary energy storage facility;
wherein the translation battery management system is configured to translate communications of the plurality of partially degraded electric vehicle batteries for communicating with the local controller.

20. The method of claim 19, wherein the stationary storage batteries and the plurality of partially degraded electric vehicle batteries are different in at least one of manufacturer, chemistry and state of health.
